(19) United States
(12) Patent Application Publication
(10) Pub. No.: US 2025/0141185 A1
(43) Pub. Date: May 1, 2025

(54) MODE-SELECTING QUANTUM CASCADE LASER

(71) Applicant: University of Central Florida Research Foundation, Inc., Orlando, FL (US)

(72) Inventors: Luke Milbocker, Orlando, FL (US); Michael Milbocker, Holliston, MA (US); Arkadiy Lyakh, Orlando, FL (US)

(21) Appl. No.: 18/934,858

(22) Filed: Nov. 1, 2024

Related U.S. Application Data
(60) Provisional application No. 63/546,847, filed on Nov. 1, 2023.

(51) Int. Cl. H01S 5/10; H01S 5/34

(52) U.S. Cl. CPC H01S 5/1007; H01S 5/101; H01S 5/1014; H01S 5/3402

(57) ABSTRACT

A quantum cascade laser (QCL) may include multiple branch waveguide regions having one or more laser cores providing optical gain at one or more output wavelengths, a stem waveguide region, and multiple couplers arranged to couple light from the plurality of branch waveguide regions to the stem waveguide region. Each of the couplers may include two or more curved waveguide regions having a continuously-varying radius of curvature providing that a fundamental transverse mode at the output wavelengths is dominant, and a coupler to combine light from the two or more curved waveguides and maintain dominance of the fundamental transverse mode at the output wavelengths. The fundamental transverse mode at the output wavelengths may be dominant in output light from the stem waveguide.

### CROSS-REFERENCE TO RELATED APPLICATION

The present application claims the benefit under 35 U.S.C. § 119 (e) of U.S. Provisional Application Ser. No. 63/546,847, filed Nov. 1, 2023, entitled MODE-SELECTING QUANTUM CASCADE LASER, naming Luke Milbocker, Michael Milbocker, and Arkadiy Lyakhas inventors, which is incorporated herein by reference in the entirety.

### GOVERNMENT LICENSE RIGHTS

This invention was made with Government support under contract W911NF22C0001 awarded by the U.S. Army Research Office. The Government has certain rights in the invention.

### TECHNICAL FIELD

The present disclosure relates generally to quantum cascade lasers and, more particularly, to single transverse mode tree-array quantum cascade lasers.

### BACKGROUND

Quantum cascade lasers (QCLs) are semiconductor lasers that achieve laser emission through intersubband transitions of energy levels within the conduction band. The energy levels result from quantum wells in a multi-layer semiconductor structure that can be designed to generate laser emission at a broad variety of infrared wavelengths. A QCL may further have multiple stages, each of which contains an electron injector region that injects carriers into active quantum wells, and in which intersubband optical transitions produce gain when sufficient current flows through the staircase of stages.

Multiple variants of QCLs have been developed. In some cases, the laser structure is grown lattice matched to an InP, GaAs, or InAs substrate by molecular beam epitaxy (MBE) or metalorganic chemical vapor deposition (MOCVD). Trenches may then be etched into the multilayer structure to create a ridge waveguide with electrical and optical confinement. The etched trenches provide lateral waveguide confinement, while the multilayer semiconductor substrate provides vertical waveguide confinement around the active region. The ridge waveguide is typically several millimeters in length, and several microns wide. In some cases, the ridge waveguide is surrounded by regrown semiconductor to form a buried heterostructure (BH) waveguide. Such a configuration may provide superior thermal management than ridge waveguide structures, but may also guide light more weakly due to lower index contrast. In either case, the wafer may then be cleaved perpendicular to the ridge to form facets that act as mirrors of the laser. Coatings may be deposited on the facets to alter their reflectivity. Laser light is amplified by electrically pumping a ridge waveguide while light bounces between the facet mirrors. Light is emitted from one or more facets due to their partial reflectivity.

A tree-array QCL is a QCL where the ridge waveguide has a branching structure. For example, multiple straight ridge waveguides on the same substrate may be joined into a single straight waveguide using a combination of curved waveguides and junctions. Tree arrays may provide relatively higher output powers than single QCLs. However, typical tree-array QCLs utilize relatively narrow waveguides to provide single transverse mode operation, which limits the achievable output power. There is therefore a need to develop systems and methods to cure the above deficiencies.

### SUMMARY

In embodiments, the techniques described herein relate to a tree-array quantum cascade laser (QCL) including a plurality of branch waveguides, where each of the plurality of branch waveguides includes one or more laser cores, where each of the one or more laser cores is formed as a multilayer quantum cascade gain medium providing optical gain at one or more output wavelengths; a stem waveguide; two or more curved waveguides, each having a continuously-varying radius of curvature configured to provide that a fundamental transverse mode at the one or more output wavelengths is dominant; and one or more couplers, where the plurality of branch waveguides are coupled to the stem waveguide through the two or more curved waveguides and the one or more couplers, where the fundamental transverse mode at the one or more output wavelengths is dominant in the stem waveguide.

In embodiments, the techniques described herein relate to a tree-array QCL, where at least one of the plurality of branch waveguides, the stem waveguide, or the one or more couplers includes a ridge waveguide.

In embodiments, the techniques described herein relate to a tree-array QCL, where at least one of the plurality of branch waveguides, the stem waveguide, or the one or more couplers includes a buried heterostructure waveguide.

In embodiments, the techniques described herein relate to a tree-array QCL, where the one or more laser cores of at least one of the plurality of branch waveguides includes two or more stages.

In embodiments, the techniques described herein relate to a tree-array QCL, where at least one of the plurality of branch waveguides or the stem waveguide have widths sufficient to support multiple transverse modes at the one or more output wavelengths.

In embodiments, the techniques described herein relate to a tree-array QCL, where the continuously-varying radius of curvature of at least one of the two or more curved waveguides has a rate of change of less than 10 mm-2.

In embodiments, the techniques described herein relate to a tree-array QCL, where the continuously-varying radius of curvature of at least one of the two or more curved waveguides is less than 0.25 mm-2.

In embodiments, the techniques described herein relate to a tree-array QCL, where at least one of the one or more couplers is a multi-mode interference (MMI) coupler.

In embodiments, the techniques described herein relate to a tree-array QCL, where a size of at least one of the two or more curved waveguides or the stem waveguide is tapered in a region adjacent to an associated one of the one or more couplers.

In embodiments, the techniques described herein relate to a tree-array QCL, where the size decreases by at least 10% in the region adjacent to the associated one of the one or more couplers.

In embodiments, the techniques described herein relate to a tree-array QCL, where a length of the stem waveguide is equal to or less than 20% of a length of the tree-array QCL.

In embodiments, the techniques described herein relate to a tree-array QCL, where a length of the stem waveguide is equal to or less than 1 mm.

In embodiments, the techniques described herein relate to a laser system including a tree-array quantum cascade laser (QCL) including a plurality of branch waveguides, where each of the plurality of branch waveguides includes one or more laser cores, where each of the one or more laser cores is formed as a multilayer quantum cascade gain medium providing optical gain at one or more output wavelengths; a stem waveguide; two or more curved waveguides, each having a continuously-varying radius of curvature configured to provide that a fundamental transverse mode at the one or more output wavelengths is dominant; and one or more couplers, where the plurality of branch waveguides are coupled to the stem waveguide through the two or more curved waveguides and the one or more couplers, where the fundamental transverse mode at the one or more output wavelengths is dominant in the stem waveguide; and a driver configured to provide a voltage across the tree-array QCL to control an emission of output light at the one or more output wavelengths.

In embodiments, the techniques described herein relate to a laser system, where the driver includes at least one of a voltage source or a current source.

In embodiments, the techniques described herein relate to a laser system, where at least one of the plurality of branch waveguides or the stem waveguide have widths sufficient to support multiple transverse modes at the one or more output wavelengths.

In embodiments, the techniques described herein relate to a laser system, where the continuously-varying radius of curvature of at least one of the two or more curved waveguides has a rate of change of less than 10 mm-2.

In embodiments, the techniques described herein relate to a laser system, where a size of at least one of the two or more curved waveguides or the stem waveguide is tapered in a region adjacent to an associated one of the one or more couplers.

In embodiments, the techniques described herein relate to a method for fabricating a tree-array quantum cascade laser (QCL) including fabricating a semiconductor layer including one or more laser cores on a substrate; patterning the semiconductor layer to provide a plurality of branch waveguides, where each of the one or more laser cores is formed as a multilayer quantum cascade gain medium providing optical gain at one or more output wavelengths; patterning the semiconductor layer to provide a stem waveguide; patterning the semiconductor layer to provide two or more curved waveguides, each having a continuously-varying radius of curvature configured to provide that a fundamental transverse mode at the one or more output wavelengths is dominant; and patterning the semiconductor layer to provide one or more couplers, where the plurality of branch waveguides are coupled to the stem waveguide through the two or more curved waveguides and the one or more couplers, where the fundamental transverse mode at the one or more output wavelengths is dominant in the stem waveguide.

In embodiments, the techniques described herein relate to a method, where at least one of the plurality of branch waveguides or the stem waveguide are formed as ridge waveguides.

In embodiments, the techniques described herein relate to a method, where at least one of the plurality of branch waveguides or the stem waveguide are formed as buried heterostructure waveguides.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A illustrates a block diagram view of a QCL laser system, in accordance with one or more embodiments of the present disclosure.

FIG. 1B illustrates a top view of a 2×1 tree-array QCL, in accordance with one or more embodiments of the present disclosure.

FIG. 1C illustrates a perspective view of the tree-array QCL in FIG. 1B, in accordance with one or more embodiments of the present disclosure.

FIG. 1D depicts a non-limiting configuration of a 4×1 tree-array QCL, in accordance with one or more embodiments of the present disclosure.

FIG. 1E is a side view of the front face of the tree-array QCL depicted in FIGS. 1B-1C, in accordance with one or more embodiments of the present disclosure.

FIG. 2 illustrates a finite element analysis (FEA) simulation of light propagation in an MMI coupler, in accordance with one or more embodiments of the present disclosure.

FIG. 3 illustrates a plot of the transmission loss of three modes in a MMI coupler as a function of a width of the MMI coupler, in accordance with one or more embodiments of the present disclosure.

FIG. 4A illustrates a plot of beam quality as a function of driving voltage for a tree-array QCL and a Fabry-Perot QCL with waveguide widths of 13 μm, in accordance with one or more embodiments of the present disclosure.

FIG. 4B illustrates a plot of beam quality as a function of driving voltage for a tree-array QCL and a Fabry-Perot QCL with waveguide widths of 15 μm, in accordance with one or more embodiments of the present disclosure.

FIG. 4C illustrates a plot of beam quality as a function of driving voltage for a tree-array QCL and a Fabry-Perot QCL with waveguide widths of 17 μm, in accordance with one or more embodiments of the present disclosure.

FIG. 5 illustrates simulated mode profiles in straight and curved waveguides, in accordance with one or more embodiments of the present disclosure.

FIG. 6 illustrates a FEA simulation of light propagating through a tree-array QCL with two straight branch waveguides coupled to a stem waveguide through curved waveguides having continuously-varying curvature and a MMI coupler, in accordance with one or more embodiments of the present disclosure.

FIG. 7 illustrates a FEA simulation of light propagating through a tree-array QCL with two straight branch waveguides coupled to a stem waveguide through curved waveguides having abrupt changes in curvature and a MMI coupler, in accordance with one or more embodiments of the present disclosure.

FIG. 8 is a simplified schematic of a tree-array QCL with tapered waveguides near a coupler, in accordance with one or more embodiments of the present disclosure.

FIG. 9 is a flow diagram illustrating steps performed in a method for fabricating a tree-array QCL, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing a tree-array quantum cascade laser (QCL) utilizing waveguides sufficiently large to allow multiple transverse modes at output wavelengths, where the QCL includes curved waveguide regions having a continuously-varying radius of curvature configured to promote single transverse mode operation. It is contemplated herein that such a configuration may provide high output powers, high brightness (e.g., high beam quality with a dominant single transverse mode), and may be fabricated with relatively high yields.

The brightness of a light source is a measure of how much power can be delivered per unit area per unit solid angle. High brightness is important for applications that require power transmission over a large distance, such as infrared countermeasures, free-space optical communications, standoff spectroscopy, etc. M² is a commonly used metric to describe the quality of a laser beam and may be defined by ISO Standard 11146. Laser beam combining for high-power, high-radiance sources is generally described in Fan, Tso Yee. “Laser beam combining for high-power, high-radiance sources.” IEEE Journal of selected topics in Quantum Electronics 11.3 (2005): 567-577; which is incorporated herein by reference in its entirety. The brightness of a laser beam can be written as:

$$B = \frac{P}{{{λ}^{2} ( {M}^{2} )}^{2}}$$

where P is the power and λ is the wavelength. As a result, the brightness of a light source such as a QCL may generally be increased by increasing output power while maintaining a good beam quality (e.g., a low M² value).

One approach to increasing brightness of a QCL is by increasing the volume of the active region contained within the waveguides. More particularly, the output power of a QCL can generally be increased by increasing a volume of an active waveguiding region. However, increasing the cross-sectional size of the active region of a QCL presents additional tradeoffs. For example, the height of the active region is directly proportional to the voltage required to power the QCL, and consequently the heat generated in the laser. Heat generation degrades QCL performance because efficiency and power output degrades at high temperatures and thus limits the ability to scale up the output power by increasing the active region height. As another example, the output power of QCL's cannot typically be increased by increasing a length of an active region since out-coupling efficiency peaks at a length of about 5 mm for typical mid-infrared QCLs.

However, increasing waveguide width (e.g., relative to the height) has shown promise for brightness scaling. Such wide waveguides may be characterized as broad area waveguides. Broad area waveguides may advantageously be designed with relatively short heights to limit the voltage required to power the QCL and relatively large widths that allow for both increased power generation and substantial heat dissipation in the vertical direction. A limiting factor for brightness scaling using broad area waveguides is the onset of multiple transverse modes that may propagate through the device, which decreases beam quality and thus the brightness.

Tree-array QCLs are another approach to increasing output power while maintaining brightness. Tree-array QCLs are generally described in Lyakh, Arkadiy, et al. “Continuous wave operation of buried heterostructure 4.6 μm quantum cascade laser Y-junctions and tree arrays.” Optics express 22.1 (2014): 1203-1208; and U.S. Pat. No. 11,901,703 issued on Feb. 13, 2024; both of which are incorporated herein by reference in their entireties. Typical tree-array QCLs include multiple single transverse mode waveguide structures one or more couplers to direct light from the single transverse mode waveguide structures into a single stem waveguide. However, various aspects of tree-array QCLs such as, but not limited to, curved waveguides and couplers may support multiple transverse modes, which again decreases beam quality and thus the brightness.

For example, CW output power of 1.5 W has been demonstrated for a 4-element tree-array with buried heterostructure (BH) waveguides and Y-junctions, which are generally described in Lyakh, Arkadiy, et al. “Continuous wave operation of buried heterostructure 4.6 μm quantum cascade laser Y-junctions and tree arrays.” Optics express 22.1 (2014): 1203-1208, which is incorporated herein by reference in its entirety. However, this configuration suffers from a complex fabrication process. To achieve in-phase operation with this configuration, each element of the array, as well as the stem, must be comprised of single transverse mode waveguides. Every mode of a waveguide has a light frequency cutoff condition that limits the laser light wavelength as a function of waveguide dimension and composition. A typical cutoff ridge width for a TM01 mode in common ridge waveguide QCLs emitting around 4.6 μm is about 5 μm. Ridge widths above this cutoff condition can support higher order transverse modes, starting with TM01. This implies a ridge width constraint of approximately 5 μm for traditional tree array QCLs. Such narrow waveguide QCLs have limited output power. Further, the hard mask used for the BH overgrowth on top of the narrow ridges does not have enough physical support to be durable, and therefore often collapses during wafer processing. As a consequence, yield for traditional tree-array QCLs is typically very low.

Embodiments of the present disclosure are directed to systems and methods providing both high power and high brightness laser output with a tree-array QCL based on broad area waveguides (e.g., wide waveguides) and continuously-curved waveguide regions designed to maintain single transverse mode operation. For example, a tree-array QCL as disclosed herein may include with relatively wide waveguides (e.g., sufficiently large to support multiple transverse modes in some cases), where at least some of the waveguides are designed to provide that a single fundamental transverse mode is dominant. As used herein, the term fundamental transverse mode refers to the transverse TM00 mode. Dominance of the fundamental transverse mode occurs when a difference of gain minus the loss is highest for the fundamental transverse mode relative to other transverse modes (e.g., higher-order transverse modes).

In some embodiments, fundamental transverse mode operation is enforced in a tree-array QCL by incorporating curved waveguides having a continuously-varying radius of curvature designed to provide that the fundamental transverse mode dominates throughout the tree-array QCL as a whole. For example, a tree-array QCL may include one or more branch waveguides having dimensions that potentially support a fundamental transverse mode and optionally support higher-order transverse modes. These branch waveguides may be substantially straight and connected to a stem waveguide through a series of curved waveguides and couplers, where the curved waveguides have continuously-varying radii of curvature that ensure fundamental transverse mode dominance. In some embodiments, the tree-array QCL further includes multi-mode interference (MMI) couplers to further enhance the dominance of the fundamental transverse mode. In this way, the curved waveguides with continuously-varying radii of curvature and/or mode selective couplers may provide relatively lower losses for the fundamental transverse mode than other modes (e.g., higher-order transverse modes) such that the fundamental transverse mode dominates at the output of the tree-array QCL. Further, it is contemplated herein that a tree-array QCL as disclosed herein may enable efficient scaling of laser power relative to single-emitter configurations. In some cases, a tree-array QCL as disclosed herein may provide an output power of 50 W or greater.

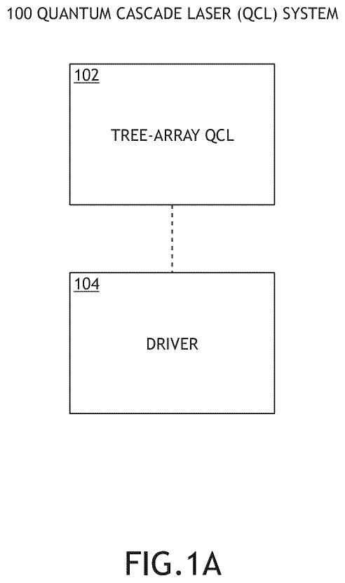

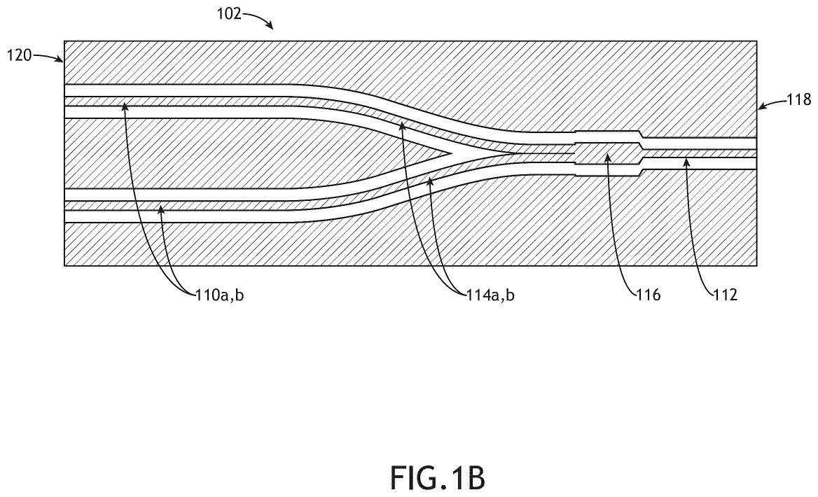

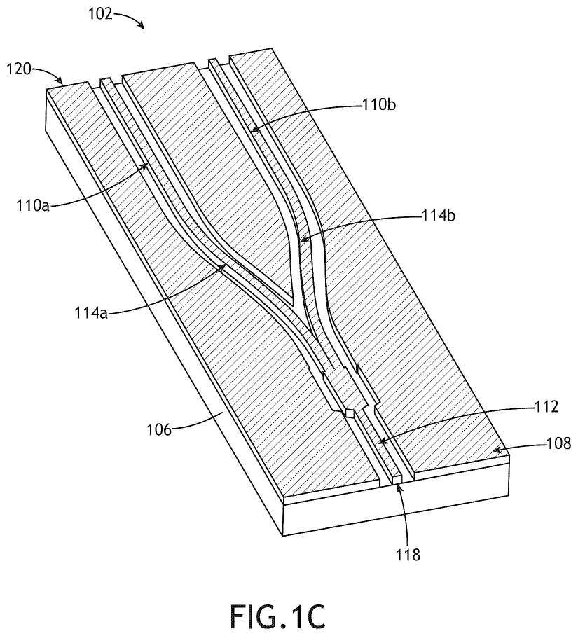

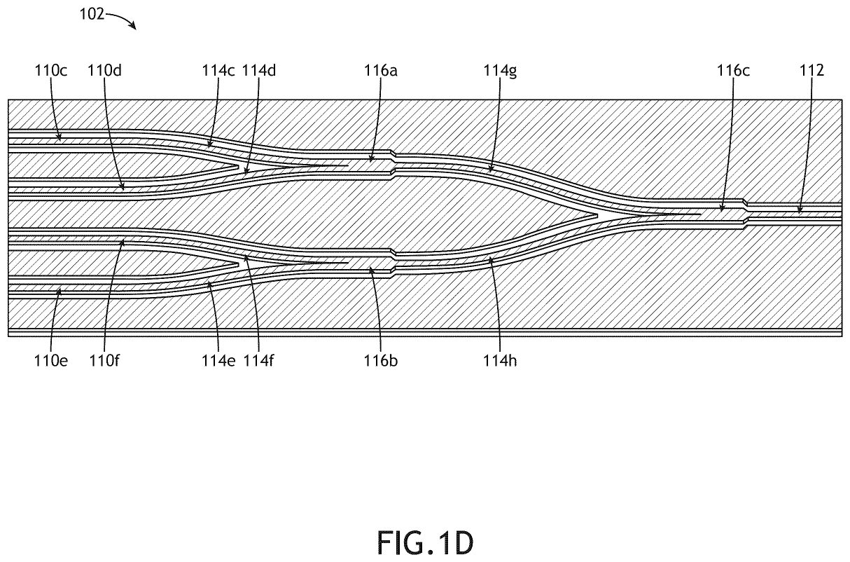

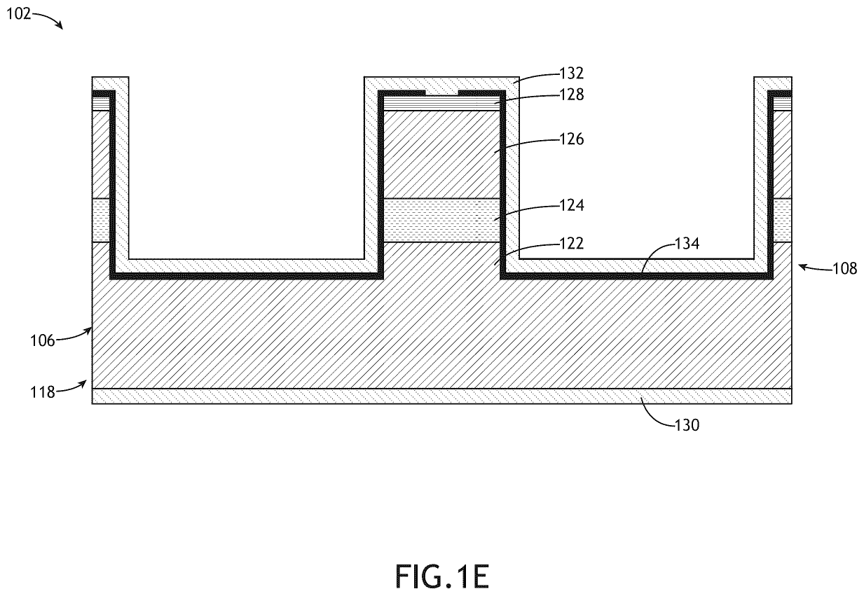

Referring now to FIGS. 1-9, systems and methods providing high-power and high-brightness laser light using a tree-array QCL, in accordance with one or more embodiments of the present disclosure.

FIG. 1A illustrates a block diagram view of a QCL laser system 100, in accordance with one or more embodiments of the present disclosure.

In some embodiments, a QCL laser system 100 includes a tree-array QCL 102 and a driver 104 to drive the tree-array QCL and control emission of output light. The driver 104 may include any combination of components suitable for inducing the tree-array QCL 102 to generate light. For example, the driver 104 may include one or more voltage and/or current sources coupled to electrically-conductive elements on the tree-array QCL 102 to apply an electric field across gain regions and inject electrons into the gain regions to produce photon emission.

FIG. 1B illustrates a top view of a tree-array QCL 102, in accordance with one or more embodiments of the present disclosure. FIG. 1C illustrates a perspective view of the tree-array QCL 102 in FIG. 1B, in accordance with one or more embodiments of the present disclosure.

In some embodiments, a tree-array QCL 102 includes a substrate 106 and a semiconductor layer 108 adjacent the substrate 106, where the semiconductor layer 108 includes a periodic arrangement of thin semiconductor materials that form a multilayer quantum cascade (QC) media providing series of cascading quantum wells suitable for light generation with high optical gain.

In some embodiments, the semiconductor layer 108 of a tree-array QCL 102 is patterned to provide various waveguiding structures (e.g., waveguides, couplers, or the like). For example, the semiconductor layer 108 may be patterned to provide two or more branch waveguides 110 (e.g., branch active regions) that converge into a stem waveguide 112 via a series of curved waveguides 114 and couplers 116. For example, the branch waveguides 110 may be, but are not required to be straight and the curved waveguides 114 may be designed to transition a separation distance between the branch waveguides 110 near a coupler 116. As an illustration, it may be desirable to provide the branch waveguides 110 with a separation of at least 100 μm for efficient heat dissipation, but provide closer spacing near the couplers 116 for efficient packing as well as requisite dimensions of the couplers 116.

A tree-array QCL 102 may generally include any number of branch waveguides 110 that converge to the stem waveguide 112 through any number of couplers 116 and curved waveguides 114 in any number of levels. Any type of couplers 116 may be utilized such as, but not limited to, Y-junctions, multi-mode interference (MMI) devices, or wavelength-selective gratings in the branch waveguides 110 and/or the stem waveguide 112.

FIG. 1B depicts a non-limiting configuration of a 2×1 tree-array QCL 102 with two branch waveguides 110 (labeled as 110a-b) that converge to a stem waveguide 112 through various curved waveguides 114 (labeled as 114a-b) and a coupler 116.

More generally, the tree-array QCL 102 may be an N×1 device with any integer number N of branch waveguides 110 that converge to a stem waveguide 112. As an illustration, FIG. 1D depicts a non-limiting configuration of a 4×1 tree-array QCL 102 with four branch waveguides 110 (labeled as 110c-f) that converge to a stem waveguide 112 through three couplers 116 (labeled as 116a-c) and various curved waveguides 114 (labeled as 114c-h) in two levels, in accordance with one or more embodiments of the present disclosure. In particular, branch waveguides 110a-b converge via first coupler 116a to a first curved waveguide 114g and branch waveguides 110c-d converge via a second coupler 116b to a second curved waveguide 114h. The first curved waveguide 114g and the second curved waveguide 114h converge via a third coupler 116c to the stem waveguide 112.

It is to be understood that the examples in FIGS. 1B-1D are merely illustrative and should not be interpreted as limiting the scope of the present disclosure. For example, although FIGS. 1B-1D depict 2×1 couplers 116, a tree-array QCL 102 may include M×1 couplers that combine light to or from any integer number M of waveguides. In this way, a tree-array QCL 102 may combine any number of branch waveguides 110 to a stem waveguide 112 in any number of levels of couplers 116 and associated curved waveguides 114.

Further, various waveguides in the tree-array QCL 102 may be arranged in any suitable manner. In some embodiments, at least some of the branch waveguides 110 are substantially parallel (e.g., parallel within +/−5 degrees) to promote efficient packing and small size, though this is not a requirement.

Any or all of the structures formed in the semiconductor layer 108 may operate as active regions suitable for generating laser light. For example, electrically-conductive materials (e.g., one or more electrically-conductive layers, one or more electrodes, or the like) may be fabricated over any portion of the semiconductor layer 108 (e.g., any combination of the branch waveguides 110, the stem waveguide 112, the couplers 116, or the curved waveguides 114). Further, light may propagate in either or both directions through the tree-array QCL 102. In this way, the tree-array QCL 102 may be configured to emit light from a front face 118 associated with the stem waveguide 112 and/or a back face 120 associated with the branch waveguides 110. As an illustration, a tree-array QCL 102 may be configured to emit light from the front face 118 by the fabrication of a reflective coating on the back face 120 and optionally anti-reflective features (e.g., one or more coatings, anti-reflective surface structures, or the like) on the front face 118. As another illustration, a tree-array QCL 102 may be configured to emit light from the back face 120 by the fabrication of a reflective coating on the front face 118 and optionally anti-reflective features (e.g., one or more coatings, anti-reflective surface structures, or the like) on the back face 120. Further, any of the waveguides may be tapered (e.g., to expand) near the front face 118 and/or the back face 120.

Referring now to FIG. 1E, the structure of the semiconductor layer 108 and the formation of waveguides are described in greater detail, in accordance with one or more embodiments of the present disclosure.

The semiconductor layer 108 may include any number of material layers providing any number of laser cores or quantum cascade stages. In some cases, the number of stages associated with the semiconductor layer 108 is less than or equal to 30. However, this is merely an illustration and should not be interpreted as limiting the scope of the present disclosure.

FIG. 1E is a side view of the front face 118 of the tree-array QCL 102 depicted in FIGS. 1B-1C, in accordance with one or more embodiments of the present disclosure.

The semiconductor layer 108 in FIG. 1E is formed from the following layer sequence: n-InP substrate lower cladding 122, InGaAs/AlInAs active region layers 124, n-InP upper cladding 126, and an n+InGaAs contact layer 128. In FIG. 1E, the semiconductor layer 108 is surrounded by a bottom contact 130 and a top contact 132. In this way, the driver 104 may induce a potential difference across the semiconductor layer 108 to provide a series of cascading quantum wells for the generation of light. The bottom contact 130 and the top contact 132 may be formed from any conductive materials. For example, the bottom contact 130 may be formed from nickel/germanium/gold and the top contact 132 may be formed from titanium/gold. However, this is merely an illustration and should not be interpreted as a limitation on the scope of the present disclosure. Additionally, a dielectric layer may be fabricated prior to any of the contacts (e.g., the top contact 132 and/or the bottom contact 130). Any dielectric material bay be used including, but not limited to silicon nitride (Si₃N₄) or silicon dioxide (SiO₂). As an illustration, FIG. 1E depicts a dielectric layer 134 beneath the top contact 132.

The various waveguides throughout the tree-array QCL 102 including, but not limited to, the branch waveguides 110, the stem waveguide 112, and the curved waveguides 114 may be formed as any type of waveguide suitable for guiding light. In some embodiments, at least some of the waveguides are formed as ridge waveguides. As an illustration, FIGS. 1B-1E depict the various waveguides (e.g., the branch waveguides 110, the stem waveguide 112, and the curved waveguides 114) as ridge waveguides formed by etching trenches in the semiconductor layer 108 to a depth below the active region layers 124. In some embodiments, at least some of the waveguides are formed as buried heterostructure (BH) waveguides.

The tree-array QCL 102 may have any total length, with typical but non-limiting values ranging from 2-12 mm. The waveguides or any other elements of the tree-array QCL 102 may have any width at any point. In some cases, the waveguides or other elements have varying widths. In some embodiments, at least some of the waveguides (e.g., at least some of the branch waveguides 110, the stem waveguide 112, and/or the curved waveguides 114) are fabricated as broad area waveguides with widths designed to promote high power operation. For example, at least some of the waveguides may have widths greater than 5 μm. As another example, at least some of the waveguides may have widths greater than 7 μm. In some cases, waveguide width is selected to mitigate optical scattering losses to provide efficient operation. As an illustration, if ridge waveguides are used, the widths may be, but are not required to be at least 8 μm to minimize optical scattering losses.

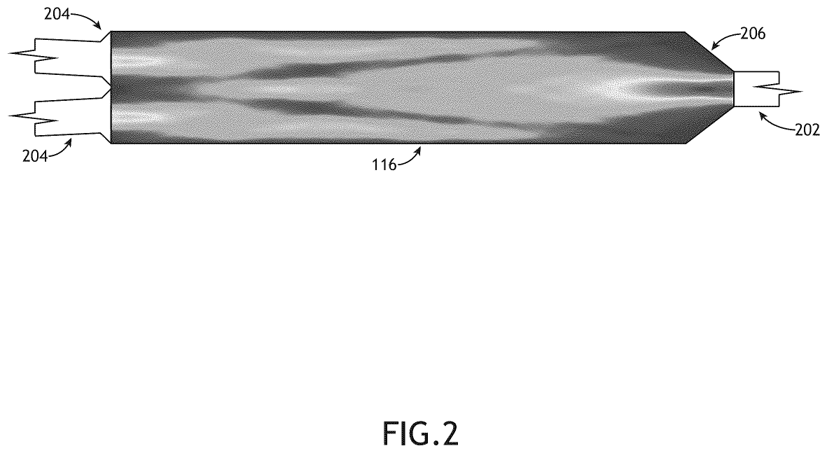

Referring now to FIGS. 2-8, various design aspects of a tree-array QCL 102 suitable for providing high-brightness laser light are described, in accordance with one or more embodiments of the present disclosure.

It is contemplated herein that a tree-array QCL 102 may be designed to provide high brightness operation through the use of broad area branch waveguides 110 and/or a broad area stem waveguide 112, where the curved waveguides 114 and/or the couplers 116 are designed to promote the dominance of the fundamental transverse mode.

In particular, a straight waveguide may be designed with a relatively wide width and a relatively small height to provide high-brightness operation (e.g., fundamental transverse mode dominance) while allowing high power operation and effective vertical heat dissipation. However, typical approaches for coupling multiple broad area branch waveguides 110 to a stem waveguide 112 may result in brightness degradation through the propagation of high-order transverse modes in non-straight sections.

In some embodiments, a tree-array QCL 102 includes one or more MMI couplers 116 designed to enforce fundamental transverse mode operation in the tree array by selecting against higher order transverse modes with high loss. MMI couplers 116 are generally described in Milbocker et al. “Beam quality analysis of mid infrared tree-array quantum cascade lasers (QCLs) based on multi-mode interference (MMI) couplers and broad-area emitters.” Novel In-Plane Semiconductor Lasers XXII. Vol. 12440. SPIE, 2023; and L. Soldano and E. Pennings, J. Lightwave Technol. 13, 615 (1995); both of which are incorporated herein by reference in its entirety.

FIG. 2 illustrates a finite element analysis (FEA) simulation of light propagation in an MMI coupler 116, in accordance with one or more embodiments of the present disclosure. The simulation in FIG. 2 depicts self-imaging of the fundamental transverse mode from the inputs to the output, in accordance with one or more embodiments of the present disclosure.

For a MMI coupler 116 containing N inputs and one output, the field distribution at the inputs will be self-imaged to the output if the following conditions are met: 1) an output waveguide 202 is located in the center of the transverse axis of the MMI coupler 116, 2) input waveguides 204 of effective width Wₑ are spaced by Wₑ/N and located symmetrically about the center of the transverse axis of the MMI coupler 116, 3) the electric field profiles of the inputs are identical and symmetrical in the transverse dimension, and 4) the length of the MMI coupler 116, L_{MMI}, satisfies

$${L}_{MMI} = \frac{{n}_{e} {W}_{e}^{2}}{N λ} ,$$

where nₑ is the effective index of the MMI coupler 116.

In some embodiments, a MMI coupler 116 has a tapered width 206 near the output waveguide 202 to suppress internal resonances. Any suitable taper angle may be used such as, but not limited to, 25 degrees.

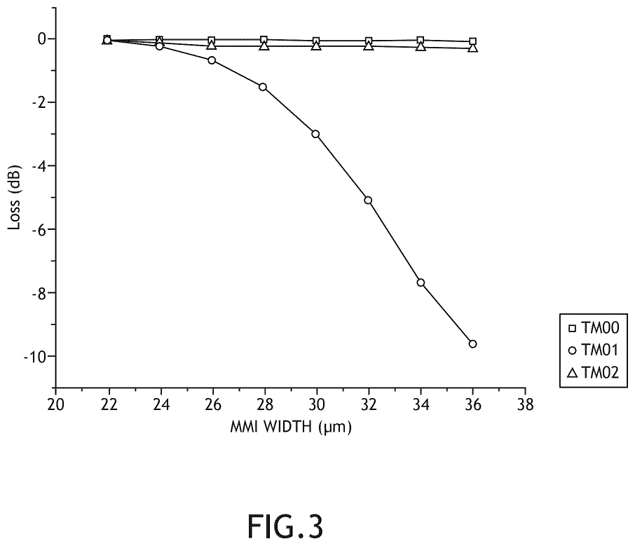

FIG. 3 illustrates a plot of the transmission loss of three modes (TM00, TM01, and TM02) in a MMI coupler 116 as a function of a width of the MMI coupler 116, in accordance with one or more embodiments of the present disclosure. In the particular design of FIG. 3, the input waveguides 204 have 10 μm widths and the loss of the TM01 greatly exceeds the loss of the fundamental TM00 mode for widths greater than 24 μm, which provides mode-selective operation in this range. For example, the loss of the TM01 mode rapidly increases with increasing width, while the losses of the TM00 and TM02 modes remain relatively constant, which is a consequence of the asymmetric electric field distribution of the TM01 mode. From FIG. 3, it is clear that wider MMI couplers 116 may be desirable for a broad area tree-array QCL 102 to achieve high suppression of the TM01 mode. However, there is a tradeoff in that the length of an MMI coupler 116 is proportional to a square of the width (e.g., as described above).

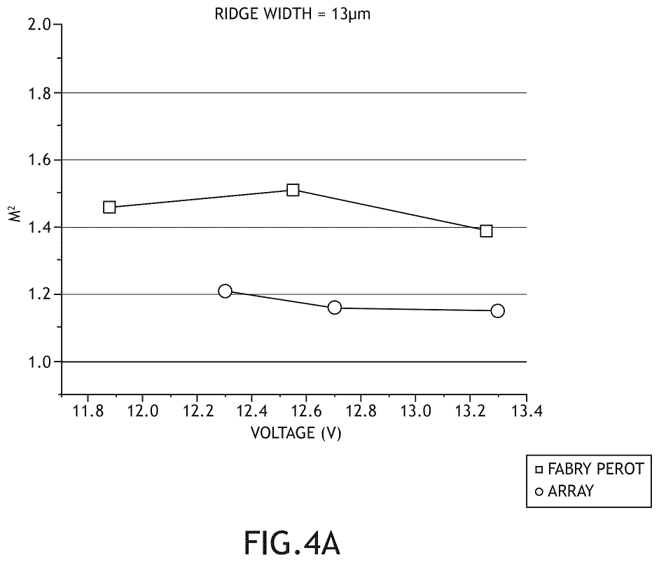

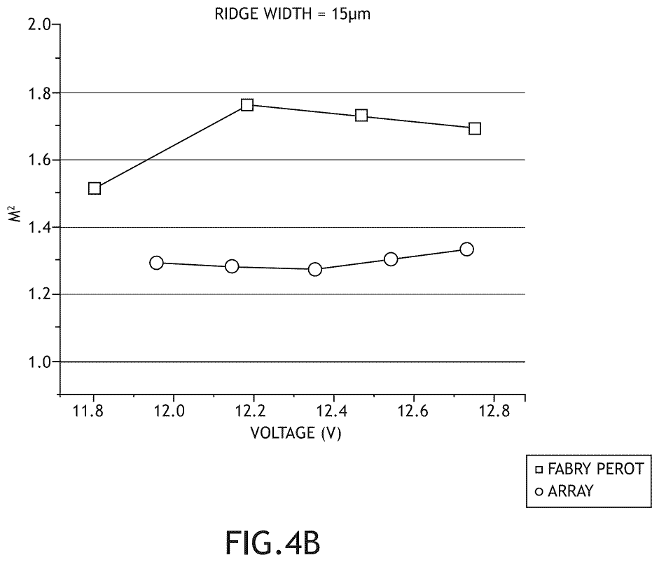

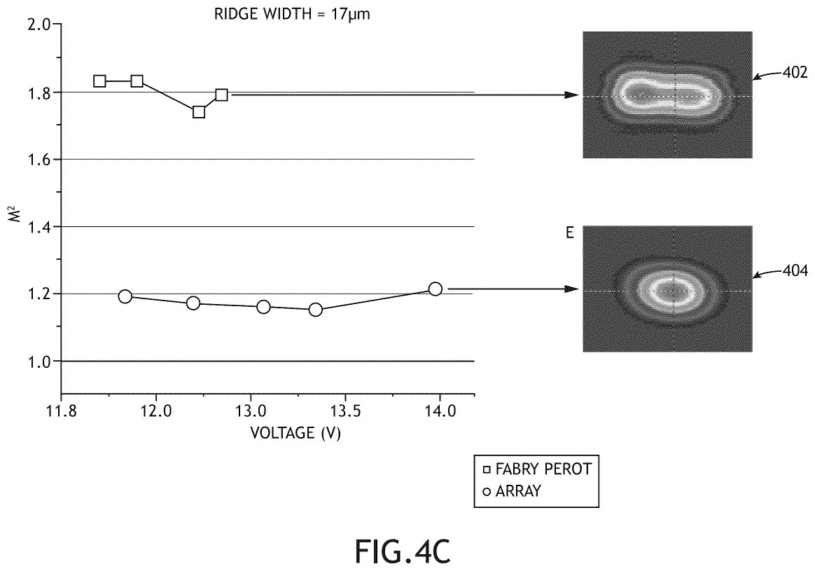

FIGS. 4A-4C illustrate high beam quality and high brightness operation for tree-array QCLs 102 with various waveguide widths (Wₑ), in accordance with one or more embodiments of the present disclosure. In FIGS. 4A-4C, performance of a tree-array QCL 102 as disclosed herein is compared to a Fabry-Perot QCL as a reference.

FIG. 4A illustrates a plot of beam quality (M²) as a function of driving voltage (e.g., provided by the driver 104) for a tree-array QCL 102 and a Fabry-Perot QCL with waveguide widths of 13 μm, in accordance with one or more embodiments of the present disclosure. FIG. 4B illustrates a plot of beam quality (M²) as a function of driving voltage for a tree-array QCL 102 and a Fabry-Perot QCL with waveguide widths of 15 μm, in accordance with one or more embodiments of the present disclosure. FIG. 4C illustrates a plot of beam quality (M²) as a function of driving voltage for a tree-array QCL 102 and a Fabry-Perot QCL with waveguide widths of 17 μm, in accordance with one or more embodiments of the present disclosure. FIG. 4C further illustrates an associated beam profile 402 of a Fabry-Perot QCL and a beam profile 404 of a tree-array QCL 102 with waveguide widths of 17 μm. As shown in FIGS. 4A-4C, a tree-array QCL 102 with MMI couplers 116 may provide high beam quality with low M² over a wide range of waveguide widths and output powers (associated with the driving voltage). In particular, the M² is consistently less than 1.4 for the tree-array QCLs 102 and consistently greater than 1.4 for the Fabry-Perot QCLs, demonstrating the improved beam quality resulting from the tree array configuration. The M² further increases with increasing ridge width for the Fabry Perot waveguides, indicating the increasing presence of higher order transverse modes such as TM01 at large ridge widths. In contrast, the M² of the tree-array QCLs 102 remains lower than 1.4 due to the mode-selective operation of the MMI couplers 116.

However, it is contemplated herein that a key element required to enforce fundamental transverse mode operation is the preservation of the fundamental transverse mode in the curved waveguides 114 leading to the couplers 116 (of any type). For example, MMI couplers 116 provide self-imaging of the beam profiles of the input waveguides 204 to the output waveguide 202. As a result, the overall beam quality and thus brightness of a tree-array QCL 102 may suffer if higher-order transverse modes are allowed at the input waveguides 204. Put another way, to obtain the fundamental transverse mode at the output of the MMI coupler, the fundamental transverse mode must be dominant at the inputs.

In some embodiments, a tree-array QCL 102 includes curved waveguides 114 that are designed to provide that that the fundamental transverse mode dominates. In this way, losses of the fundamental TM00 mode may be lower than losses of at least some higher-order modes in the curved waveguides 114. Further, in some embodiments, the curved waveguides 114 are designed to provide that the fundamental transverse mode dominates at the inputs of the couplers 116 (e.g., MMI couplers 116 or any other suitable couplers 116). Such a configuration may allow greater flexibility for waveguide width throughout the tree-array QCL 102 (e.g., in the branch waveguides 110, the stem waveguide 112, or the like) to promote high-power operation, ease of fabrication, or the like.

In some embodiments, a tree-array QCL 102 includes curved waveguides 114 having a continuously-varying radius of curvature designed to promote fundamental transverse mode dominance. For example, a curved waveguide 114 may be formed as an S-bend having a curvature that varies linearly such that the radius of curvature approaches infinity in three places: where the S-bend meets a branch waveguide 110, where the S-bend meet the coupler 116, and where the curvature in the S-bend changes direction. The curvature in the S-bends may be in the form of a Euler Spiral, which can be described parametrically by:

$$x = \frac{1}{a} {\int }_{0}^{{L}^{′}} cos ( {s}^{2} ) ds$$

$$y = \frac{1}{a} {\int }_{0}^{{L}^{′}} sin ( {s}^{2} ) ds$$

For example, a waveguide possessing a continuously varying curvature resembling a Euler spiral may be used to minimize the transmission loss of the fundamental transverse mode from the branch sections to the stem section, where a high-quality beam is emitted.

It is contemplated herein that a curved waveguide 114 may be designed to promote dominance of the fundamental transverse mode by avoiding abrupt changes in curvature. In some embodiments, a rate of change of curvature of a curved waveguide 114 is maintained below a threshold selected to ensure dominance of the fundamental transverse mode through the curved waveguide. As a non-limiting illustration, the rate of change of curvature may be maintained below 10 mm-2. As another non-limiting illustration, the rate of change of curvature may be maintained below 0.25 mm-2. It is to be understood that the particular threshold required to ensure dominance of the fundamental transverse mode may be influenced by a variety of factors such as, but not limited to, wavelength and waveguide dimensions (e.g., width and/or height).

For example, a tree-array QCL with curved waveguides that have a constant radius of curvature was demonstrated in Lyakh, Arkadiy, et al. “Continuous wave operation of buried heterostructure 4.6 μm quantum cascade laser Y-junctions and tree arrays.” Optics express 22.1 (2014): 1203-1208; and U.S. Pat. No. 11,901,703 issued on Feb. 13, 2024; both of which are incorporated herein by reference in their entireties. However, branched waveguide structures such as those in the above reference without slow variations in the waveguide curvature require narrow waveguides for good beam quality. This requirement for narrow waveguides limits the area of the active region and hence the brightness output of the laser. Further, in-phase operation can only be achieved for narrow waveguides where the fundamental transverse mode dominates.

It is further noted that the necessity to use narrow waveguides in previously demonstrated QCL arrays was at least in part caused by the excitation of multiple transverse modes when straight waveguides are coupled to constant curvature waveguides that can support multiple transverse modes. The excitation of multiple transverse modes degrades the beam quality of QCL arrays, especially when couplers are used that require fundamental transverse mode operation.

For example, when a straight waveguide operating in TM00 meets a curved waveguide that supports multiple transverse modes, multiple transverse modes can be excited due to spatial overlap of the field profiles between the straight and curved waveguide modes. For a curved waveguide with a constant radius of curvature on the order of 1 mm that is typical for QCL arrays, multiple modes will be excited at the transition from the straight waveguide to the curved waveguide because the curved waveguide supports multiple transverse modes. The excitation of multiple transverse modes results in coupling loss to the TM00 mode. This makes fundamental transverse mode operation in QCL arrays unlikely if the ridge width is wide enough to support multiple transverse modes and a constant radius of curvature is used in the curved waveguides.

In contrast, embodiments of the present disclosure providing a tree-array QCL 102 with curved waveguides 114 having continuously-varying curvature allows for wider waveguides (e.g., wider branch waveguides 110 and/or a wider stem waveguide 112), which enables an increase in the output power of the tree-array QCL 102 while maintaining fundamental transverse mode operation and good beam quality. Further, a tree-array QCL 102 as disclosed herein may include waveguides (e.g., branch waveguides 110 and/or a stem waveguide 112) having widths sufficiently large to support the propagation of multiple transverse modes, where the curved waveguides 114 are designed to suppress higher order transverse modes and provide relatively lower loss for the fundamental transverse mode to ensure high beam quality and brightness of the tree-array QCL 102 as a whole. Put another way, the fundamental transverse mode dominates because the difference in the gain minus the losses is highest for the fundamental transverse mode.

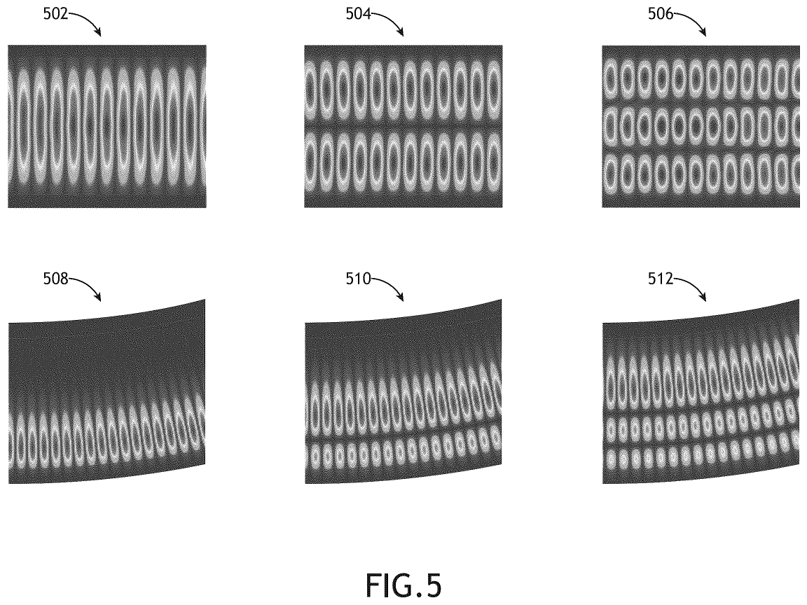

Referring now to FIGS. 5-7, simulations of mode propagation in straight and curved waveguides are described.

FIG. 5 illustrates simulated mode profiles in straight and curved waveguides, in accordance with one or more embodiments of the present disclosure. In particular, plots 502-506 depicts simulated mode profiles in a straight waveguide, while plots 508-12 depict simulated mode profiles in a curved waveguide with a constant curvature. It is contemplated herein that the mode shown in plot 502 mode for a straight waveguide might excite a combination of the transverse modes shown in plots 508-512 in a curved waveguide having a constant curvature. However, by slowly varying the curvature along the length of the waveguide (e.g., a curved waveguide 114 as disclosed herein), the mode shown in plot 502 may couple almost entirely into the mode shown in plot 508 and exclude the transverse modes shown in plots 510-512 since the mode shown in plot 502 may efficiently couple into many intermediate modes that are supported by the changing curvature without exciting higher-order transverse modes.

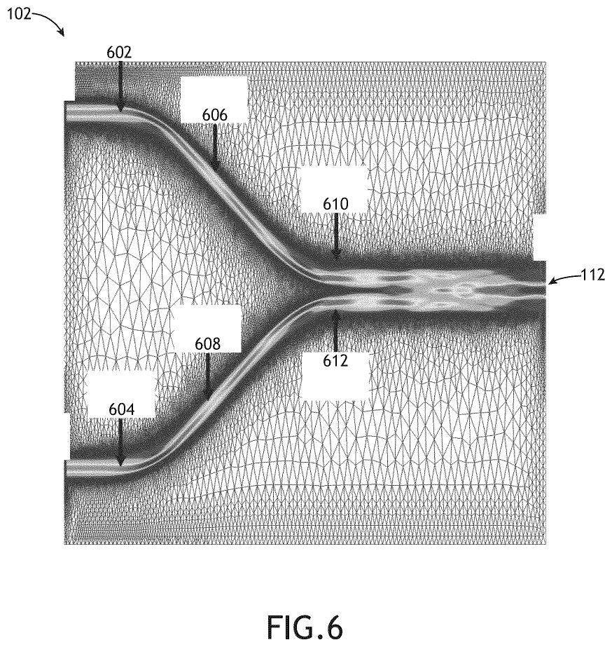

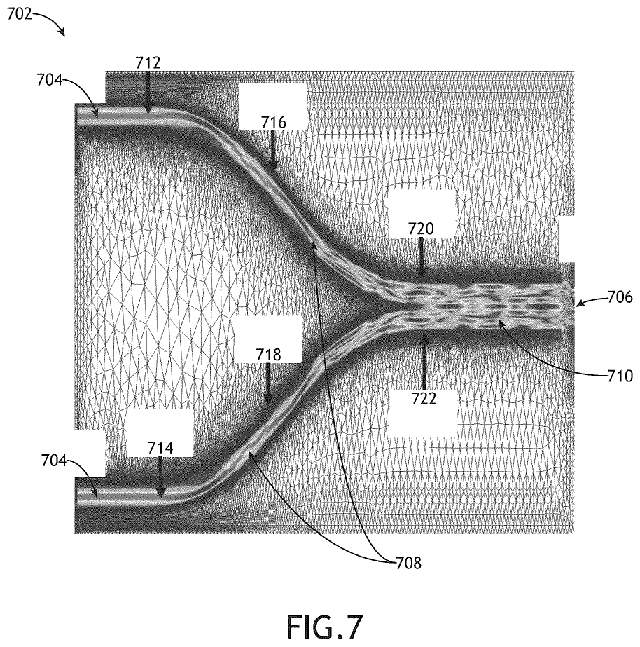

FIGS. 6-7 highlight the impact of abrupt curvature changes on the propagation of transverse modes throughout a tree-array QCL 102.

FIG. 6 illustrates a FEA simulation of light propagating through a tree-array QCL 102 with two straight branch waveguides 110 coupled to a stem waveguide 112 through curved waveguides 114 having continuously-varying curvature and a MMI coupler 116, in accordance with one or more embodiments of the present disclosure. In FIG. 6, the curved waveguides 114 have continuously-varying curvature, where the curvature approaches infinity at locations 602/604 near an interface with the branch waveguides 110, at points 606/608 at a point where the curvature changes directions, and at points 610/612 near an interface with the MMI coupler 116. As a result, the fundamental transverse mode present in the branch waveguides 110 is coupled into the curved waveguides 114 without excitation of higher-order transverse modes such that the fundamental transverse mode is present at the inputs of the MMI coupler 116 and thus at the input to the stem waveguide 112.

FIG. 7 illustrates a FEA simulation of light propagating through a tree-array QCL 702 with two straight branch waveguides 704 coupled to a stem waveguide 706 through curved waveguides 708 having abrupt changes in curvature and a MMI coupler 710, in accordance with one or more embodiments of the present disclosure. For example, abrupt changes in curvature occur at points 712/714, 716/718, and 720/722.

In contrast to FIG. 6, the abrupt changes in curvature present in the curved waveguides 708 of FIG. 7 result in the excitation of higher-order transverse modes in the curved waveguides 708 that are present at the inputs of the MMI coupler 710. These higher-order transverse modes then propagate through the MMI coupler 710 and are present at the input to a stem waveguide 706. This is because the MMI coupler 710 relies on fundamental transverse mode operation at the inputs to produce the fundamental transverse mode at the output. The resulting beam in the stem waveguide 712 has limited output power, beam quality, and brightness compared to the beam in the stem waveguide 112 of FIG. 6.

Referring now generally to FIGS. 1A-9, various additional considerations for designing a tree-array QCL 102 are described, in accordance with one or more embodiments of the present disclosure.

In some embodiments, waveguides of a tree-array QCL 102 are tapered to be relatively wider at the facets of the device. This may be done to decrease the optical power density at the facet to prevent catastrophic optical damage, which is a common limiter of QCL output power.

Waveguides of a tree-array QCL 102 may also be tapered near any or all of the couplers 116. In some embodiments, waveguides are tapered to be relatively wider near the couplers 116, which may improve the efficiency of the coupler. In some embodiments, waveguides are tapered to be relatively narrower near the couplers 116. It is contemplated herein that thermal lensing caused by heating of the laser waveguides can reduce the transmission efficiency of junction couplers 116 such as MMI couplers 116. Thermal lensing in or around the waveguide couplers may be reduced by reducing waveguide size near the input and/or output regions since smaller waveguides may generate less heat and dissipate the heat more efficiently. Such a configuration further allows relatively wider waveguides throughout other portions of the QCL to maximize output power.

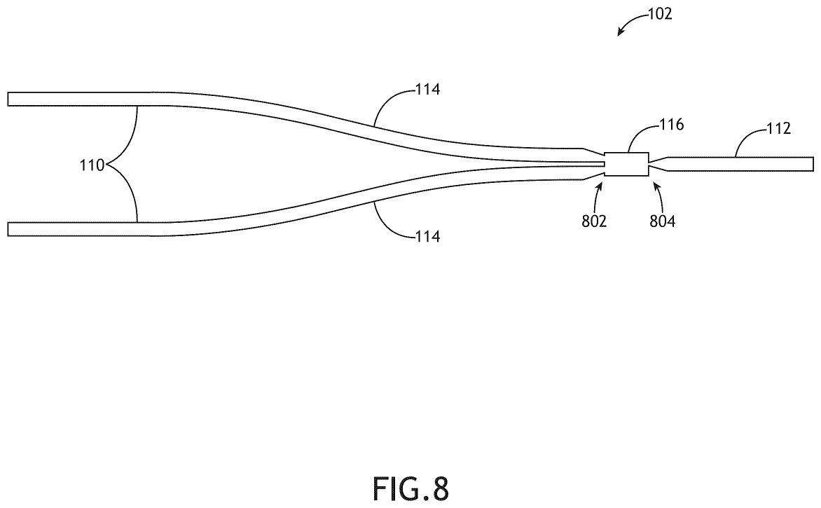

FIG. 8 is a simplified schematic of a tree-array QCL 102 with tapered waveguides near a coupler 116, in accordance with one or more embodiments of the present disclosure. FIG. 8 is substantially similar to FIG. 1B, but with tapered waveguides. In particular, FIG. 8 depicts a non-limiting configuration in which the curved waveguides 114 are tapered to provide narrower widths near the coupler 116 (e.g., in regions adjacent to the associated coupler 116). Similarly, the stem waveguide 112 is tapered to provide a narrower width near the coupler 116.

The taper regions 802/804 may have any suitable length and provide tapering by any amount. For example, the lengths of the taper regions 802/804 may be selected to prevent or mitigate exciting high-order transverse modes in the region. As another example, the waveguide size (e.g., width, height, and/or area) may be changed to narrow or widen the waveguides by any suitable percentage including, 5%, 10%, 20%, 50% or more. As a non-limiting illustration, a tree-array QCL 102 with ridge waveguides that are 20 μm wide throughout most of the array can have waveguide tapers that reduce the ridge width to 10 μm at the inputs and outputs of MMI couplers 116.

In some embodiments, a length of the stem waveguide 112 of a tree-array QCL 102 is selected to mitigate and/or prevent gain saturation. It is contemplated herein that gain saturation by high optical intensities inside the active region reduces the efficiency of long tree-array QCL 102 and is the primary reason why typical tree-array QCLs rarely exceed 10 mm in length. In the tree-array configuration, gain saturation can also reduce the efficiency of QCLs at much shorter lengths because the optical intensity is very high in certain parts of a tree-array. For example, an uncoated tree-array QCL 102 may have the highest optical intensity in the stem waveguide 112, leading to gain saturation in the stem waveguide 112 and reduced efficiency overall. Reducing the length of the stem waveguide 112 can therefore increase the efficiency of a tree-array QCL 102, especially if the tree-array QCL 102 is configured to emit its beam from the stem waveguide 112. The stem waveguide 112 of a tree-array QCL 102 may have any suitable length. For example, the stem waveguide 112 may have a length selected to be 15% or less than a total length of the tree-array QCL 102 as a whole. As another example, the stem waveguide 112 may have a length of approximately 1 mm. As another example, the length of the stem waveguide 112 may be as short as achievable using a particular fabrication technique.

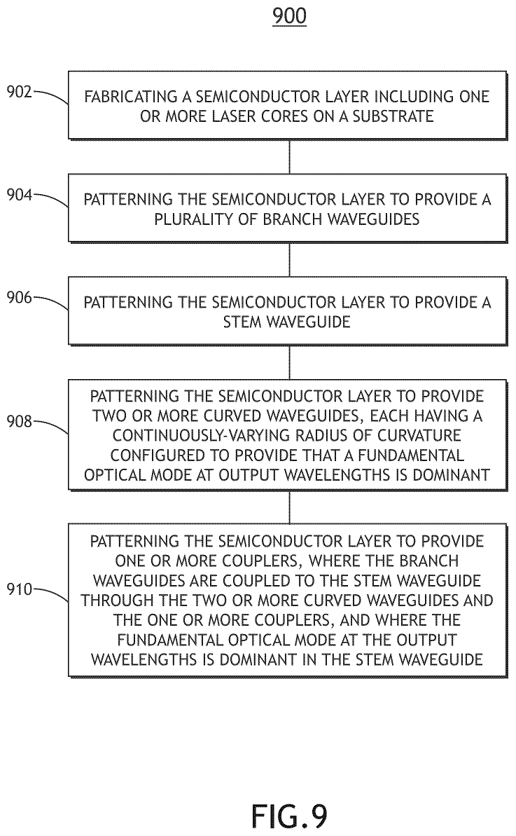

FIG. 9 is a flow diagram illustrating steps performed in a method 900 for fabricating a tree-array QCL 102, in accordance with one or more embodiments of the present disclosure. The embodiments and enabling technologies described previously herein in the context of the QCL laser system 100 should be interpreted to extend to the method 900. It is further noted, however, that the method 900 is not limited to the architecture of the QCL laser system 100.

The method 900 may include a step 902 of fabricating a semiconductor layer 108 including one or more laser cores on a substrate 106. The method 900 may include a step 904 of patterning the semiconductor layer 108 to provide a plurality of branch waveguides 110. Further, each of the branch waveguides 110 includes one or more laser cores, and where each of the laser cores is formed as a multilayer quantum cascade gain medium providing optical gain at one or more output wavelengths. For example, each of the laser cores may have, but is not required to have, less than 30 cores.

The method 900 may include a step 906 of patterning the semiconductor layer 108 to provide a stem waveguide 112. The method 900 may include a step 908 of patterning the semiconductor layer 108 to provide two or more curved waveguides 114, each having a continuously-varying radius of curvature configured to provide that a fundamental transverse mode at output wavelengths is dominant. The method 900 may include a step 910 of patterning the semiconductor layer to provide one or more couplers 116, where the branch waveguides 110 are coupled to the stem waveguide 112 through the two or more curved waveguides 114 and the one or more couplers 116, and where the fundamental transverse mode at the output wavelengths is dominant in the stem waveguide 112.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A tree-array quantum cascade laser (QCL) comprising:
a plurality of branch waveguides, wherein each of the plurality of branch waveguides includes one or more laser cores, wherein each of the one or more laser cores is formed as a multilayer quantum cascade gain medium providing optical gain at one or more output wavelengths;
a stem waveguide;
two or more curved waveguides, each having a continuously-varying radius of curvature configured to provide that a fundamental transverse mode at the one or more output wavelengths is dominant; and
one or more couplers, wherein the plurality of branch waveguides are coupled to the stem waveguide through the two or more curved waveguides and the one or more couplers, wherein the fundamental transverse mode at the one or more output wavelengths is dominant in the stem waveguide.

2. The tree-array QCL of claim 1, wherein at least one of the plurality of branch waveguides, the stem waveguide, or the one or more couplers includes a ridge waveguide.

3. The tree-array QCL of claim 1, wherein at least one of the plurality of branch waveguides, the stem waveguide, or the one or more couplers includes a buried heterostructure waveguide.

4. The tree-array QCL of claim 1, wherein the one or more laser cores of at least one of the plurality of branch waveguides includes two or more stages.

5. The tree-array QCL of claim 1, wherein at least one of the plurality of branch waveguides or the stem waveguide have widths sufficient to support multiple transverse modes at the one or more output wavelengths.

6. The tree-array QCL of claim 1, wherein the continuously-varying radius of curvature of at least one of the two or more curved waveguides has a rate of change of less than 10 mm-2.

7. The tree-array QCL of claim 1, wherein the continuously-varying radius of curvature of at least one of the two or more curved waveguides is less than 0.25 mm⁻².

8. The tree-array QCL of claim 1, wherein at least one of the one or more couplers is a multi-mode interference (MMI) coupler.

9. The tree-array QCL of claim 1, wherein a size of at least one of the two or more curved waveguides or the stem waveguide is tapered in a region adjacent to an associated one of the one or more couplers.

10. The tree-array QCL of claim 9, wherein the size decreases by at least 10% in the region adjacent to the associated one of the one or more couplers.

11. The tree-array QCL of claim 1, wherein a length of the stem waveguide is equal to or less than 20% of a length of the tree-array QCL.

12. The tree-array QCL of claim 1, wherein a length of the stem waveguide is equal to or less than 1 mm.

13. A laser system comprising:
a tree-array quantum cascade laser (QCL) comprising:
a plurality of branch waveguides, wherein each of the plurality of branch waveguides includes one or more laser cores, wherein each of the one or more laser cores is formed as a multilayer quantum cascade gain medium providing optical gain at one or more output wavelengths;
a stem waveguide;
two or more curved waveguides, each having a continuously-varying radius of curvature configured to provide that a fundamental transverse mode at the one or more output wavelengths is dominant; and
one or more couplers, wherein the plurality of branch waveguides are coupled to the stem waveguide through the two or more curved waveguides and the one or more couplers, wherein the fundamental transverse mode at the one or more output wavelengths is dominant in the stem waveguide; and
a driver configured to provide a voltage across the tree-array QCL to control an emission of output light at the one or more output wavelengths.

14. The laser system of claim 13, wherein the driver includes at least one of a voltage source or a current source.

15. The laser system of claim 13, wherein at least one of the plurality of branch waveguides or the stem waveguide have widths sufficient to support multiple transverse modes at the one or more output wavelengths.

16. The laser system of claim 13, wherein the continuously-varying radius of curvature of at least one of the two or more curved waveguides has a rate of change of less than 10 mm⁻².

17. The laser system of claim 13, wherein a size of at least one of the two or more curved waveguides or the stem waveguide is tapered in a region adjacent to an associated one of the one or more couplers.

18. A method for fabricating a tree-array quantum cascade laser (QCL) comprising:
fabricating a semiconductor layer including one or more laser cores on a substrate;
patterning the semiconductor layer to provide a plurality of branch waveguides, wherein each of the one or more laser cores is formed as a multilayer quantum cascade gain medium providing optical gain at one or more output wavelengths;
patterning the semiconductor layer to provide a stem waveguide;
patterning the semiconductor layer to provide two or more curved waveguides, each having a continuously-varying radius of curvature configured to provide that a fundamental transverse mode at the one or more output wavelengths is dominant; and
patterning the semiconductor layer to provide one or more couplers, wherein the plurality of branch waveguides are coupled to the stem waveguide through the two or more curved waveguides and the one or more couplers, wherein the fundamental transverse mode at the one or more output wavelengths is dominant in the stem waveguide.

19. The method of claim 18, wherein at least one of the plurality of branch waveguides or the stem waveguide are formed as ridge waveguides.

20. The method of claim 18, wherein at least one of the plurality of branch waveguides or the stem waveguide are formed as buried heterostructure waveguides.
